(19) United States
(12) Patent Application Publication
(10) Pub. No.: US 2024/0421082 A1
(43) Pub. Date: Dec. 19, 2024

(54) SEMICONDUCTOR DEVICE

(71) Applicant: Samsung Electronics Co., Ltd., Suwon-si (KR)

(72) Inventors: Jeon Won Jeong, Suwon-si (KR); Yubo Qian, Suwon-si (KR); Sutae Kim, Suwon-si (KR); Jae Young Park, Suwon-si (KR); Jin Woo Lee, Suwon-si (KR)

(21) Appl. No.: 18/662,042

(22) Filed: May 13, 2024

(30) Foreign Application Priority Data
Jun. 16, 2023 (KR) 10-2023-0077618

(51) Int. Cl. H01L 23/528; H01L 29/06; H01L 29/417; H01L 29/423; H01L 29/775; H01L 29/786

(52) U.S. Cl. CPC H01L 23/5283; H01L 29/0673; H01L 29/41733; H01L 29/42392; H01L 29/775; H01L 29/78696

(57) ABSTRACT

A semiconductor device includes a substrate including a standard cell area and an ending cell area that at least partially surrounds the standard cell area; a first active pattern in the standard cell area; a first wiring that extends in a first direction and is on the first active pattern; a first gate electrode that extends in a second direction and is on the first active pattern; a first gate contact; a second active pattern in the ending cell area; a second wiring that extends in the first direction and is on the second active pattern; a second gate electrode that extends in the second direction and is on the second active pattern; and a second gate contact.

This application claims the benefit of Korean Patent Application No. 10-2023-0077618, filed on Jun. 16, 2023, in the Korean Intellectual Property Office, the disclosure of which is incorporated herein in its entirety by reference.

### TECHNICAL FIELD

The present disclosure relates to a semiconductor device.

### BACKGROUND

As semiconductor devices become more highly integrated, it may be desirable to add dummy patterns to solve various problems arising in a process of manufacturing a semiconductor device, such as pattern uniformity, etching process margin, and deterioration of mechanical properties of interlayer insulating layers.

### SUMMARY

Aspects of the present disclosure provide a semiconductor device that includes gate contacts disposed in an ending cell area.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a semiconductor device includes a substrate including a standard cell area and an ending cell area that at least partially surrounds the standard cell area; a first active pattern in the standard cell area; a first wiring that extends in a first direction and is on the first active pattern; a first gate electrode that extends in a second direction and is on the first active pattern; a first gate contact; a second active pattern in the ending cell area; a second wiring that extends in the first direction and is on the second active pattern; a second gate electrode that extends in the second direction and is on the second active pattern; and a second gate contact.

According to another aspect of the present disclosure, a semiconductor device includes a substrate including a standard cell area and an ending cell area that at least partially surrounds the standard cell area; an active pattern in the ending cell area; a power rail that extends in a first direction and is on the active pattern; a wiring that extends in the first direction and is on the active pattern; one or more gate electrodes that extend in a second direction and are on the active pattern; a gate contact between the gate electrode and the wiring; a source/drain pattern on the active pattern and on one side of the gate electrode; and a well contact between the source/drain pattern and the power rail.

According to another aspect of the present disclosure, a semiconductor device includes a substrate; a first active pattern on the substrate; a second active pattern on the substrate; a first gate electrode that is on the first active pattern and extends in a second direction; a second gate electrode that is on the second active pattern and extends in the second direction; a first wiring that extends in a first direction and is on the first active pattern; a second wiring that extends in the first direction and is on the second active pattern; a power rail that extends in the first direction and is on the substrate; a first gate contact between the first gate electrode and the first wiring; and a second gate contact between the second gate electrode and the second wiring, where the second active pattern is electrically connected to the power rail, and where the first wiring and the second wiring are not electrically connected to each other.

### BRIEF DESCRIPTION OF THE DRAWINGS

These and/or other aspects will become apparent and more readily appreciated from the following description of the embodiments, taken in conjunction with the accompanying drawings in which:

FIG. 1 is a layout view of a semiconductor device according to embodiments of the present disclosure;

FIG. 2 is an enlarged view of area R of FIG. 1;

FIG. 3 is a cross-sectional view taken along line A-A′ of FIG. 2;

FIG. 4 is a cross-sectional view taken along line B-B′ of FIG. 2;

FIG. 5 is a cross-sectional view taken along line C-C′ of FIG. 2;

FIG. 6 is a cross-sectional view taken along line D-D′ of FIG. 2;

FIG. 7 is a cross-sectional view taken along line E-E′ of FIG. 2;

FIG. 8 is a cross-sectional view taken along line F-F′ of FIG. 2;

FIG. 9 is a cross-sectional view taken along line G-G′ of FIG. 2;

FIGS. 10, 11, 12, 13, 14, 15, and 16 are cross-sectional views of a semiconductor device according to embodiments of the present disclosure; and

FIG. 17 is a layout view of a semiconductor device according to embodiments of the present disclosure.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

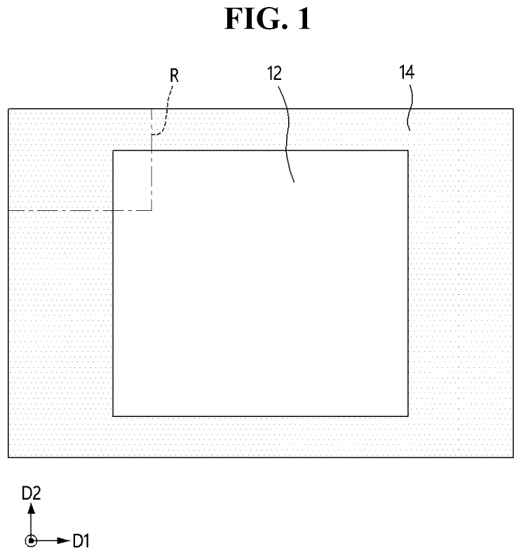

FIG. 1 is a layout view of a semiconductor device according to embodiments.

Referring to FIG. 1, the semiconductor device according to the embodiments may include a standard cell area 12 and an ending cell area 14.

One or more standard cells are disposed in the standard cell area 12. Each of the standard cells may refer to a unit of an integrated circuit whose layout size satisfies a predetermined rule. Heights of the standard cells may be constant, and widths of the standard cells may be different. The standard cells may include single-height cells disposed in one row and multi-height cells corresponding to a plurality of rows. Each of the standard cells may include an input pin and an output pin and may process an input signal received through the input pin and output an output signal through the output pin. For example, the standard cells may include basic cells such as AND, OR, NOR and inverters, complex cells such as OR/AND/INVERTER (OAI) and AND/OR/INVERTER (AOI), and storage elements such as master-slave flip-flops and latches.

The ending cell area 14 is disposed at edges of the standard cell area 12 such that the ending cell area 14 at least partially surrounds the standard cell area 12. A plurality of ending cells are disposed in the ending cell area 14. The ending cells may refer to cells disposed around the standard cells to reduce a proximity effect from nearby cells. The ending cells may refer to ending cap cells, beginning cells, or dummy cells.

For example, the ending cell area 14 may be disposed at left and right edges of the standard cell area 12 in a first direction D1. The ending cells may be disposed at the left and right edges of the standard cell area 12 in the first direction D1 and may be successively disposed along a second direction D2. As another example, the ending cell area 14 may be further disposed at upper and lower edges of the standard cell area 12 in the second direction D2 and may surround the standard cell area 12. The ending cells may be further disposed at the upper and lower edges of the standard cell area 12 in the second direction D2 and may be successively disposed along the first direction D1.

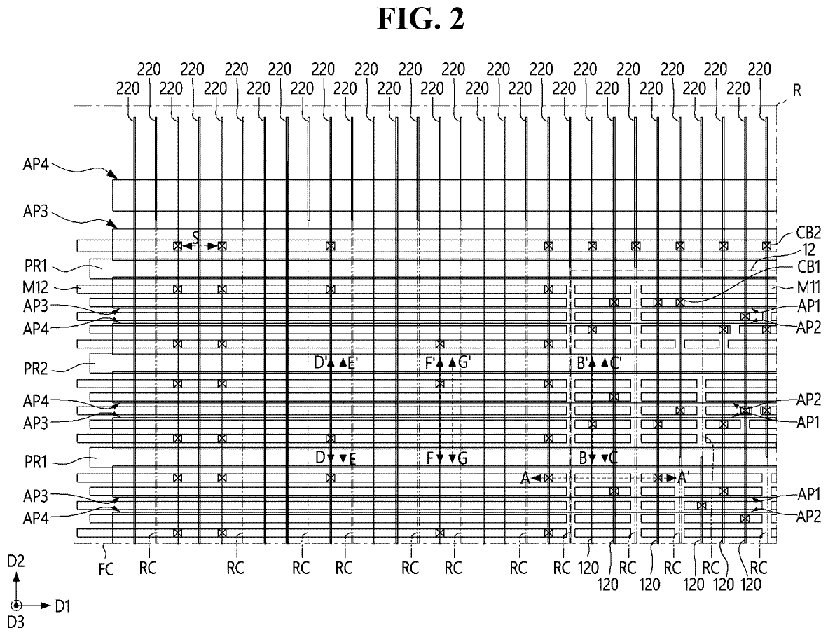

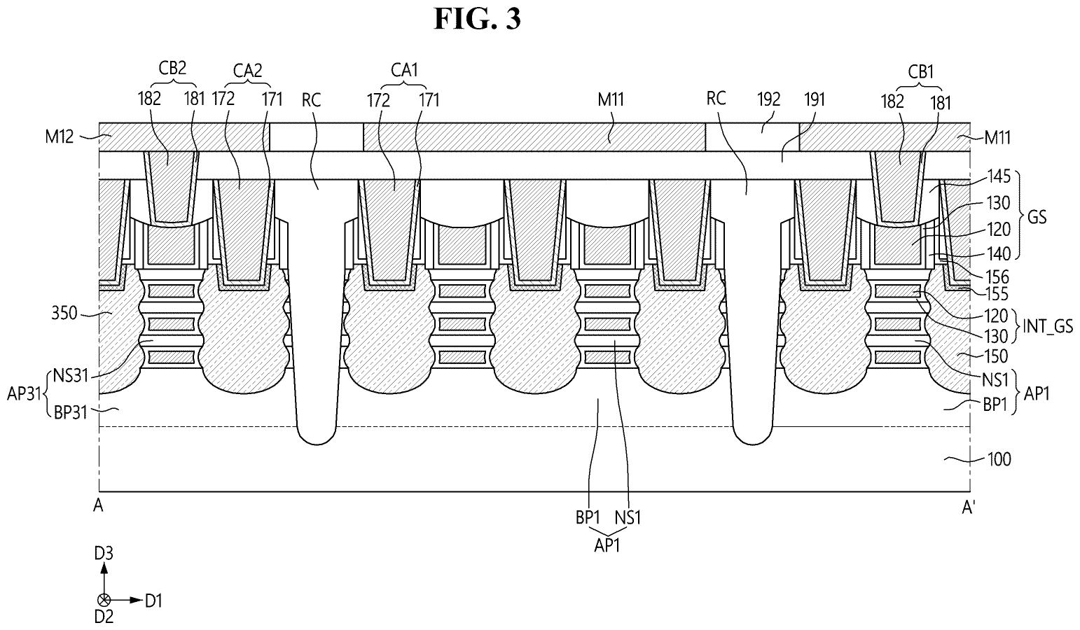

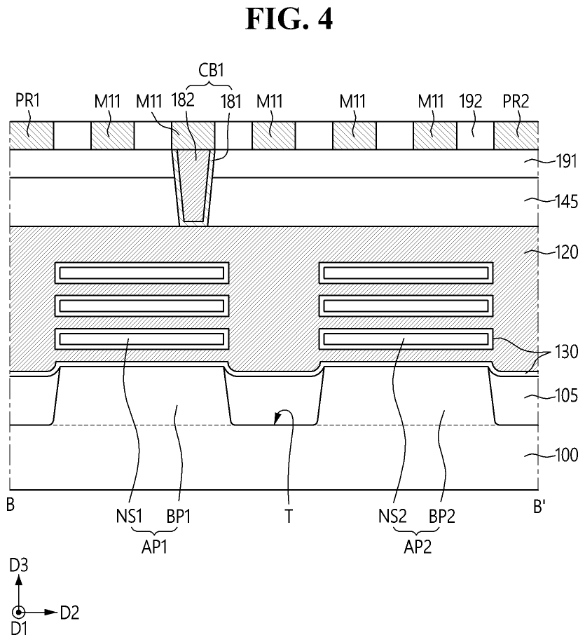

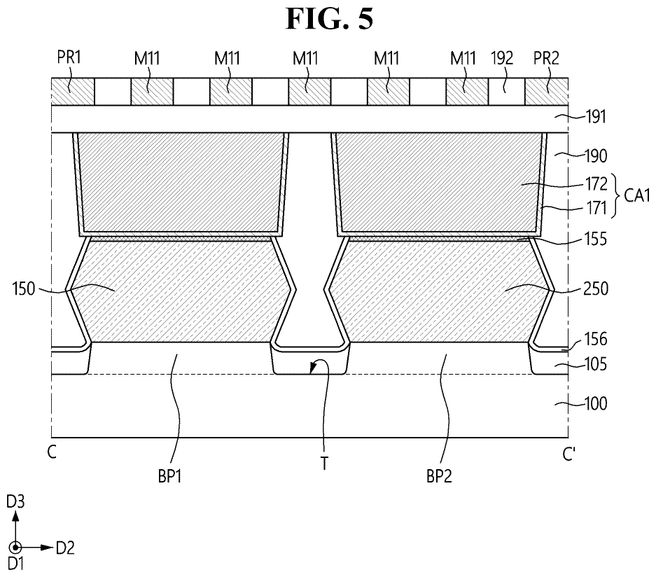

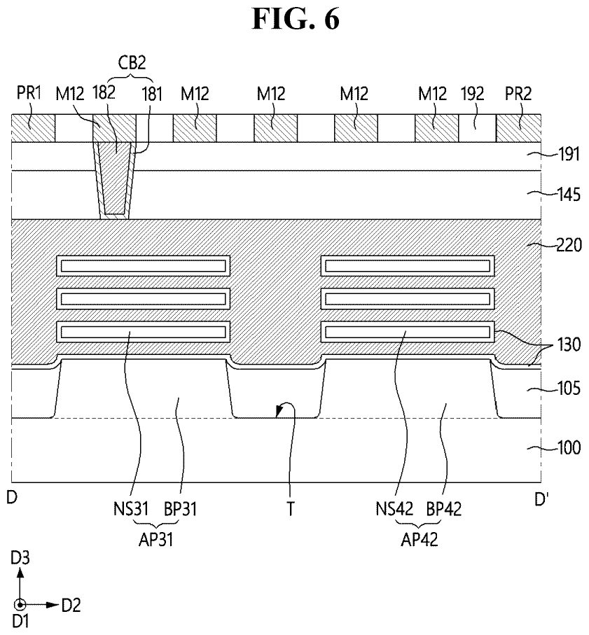

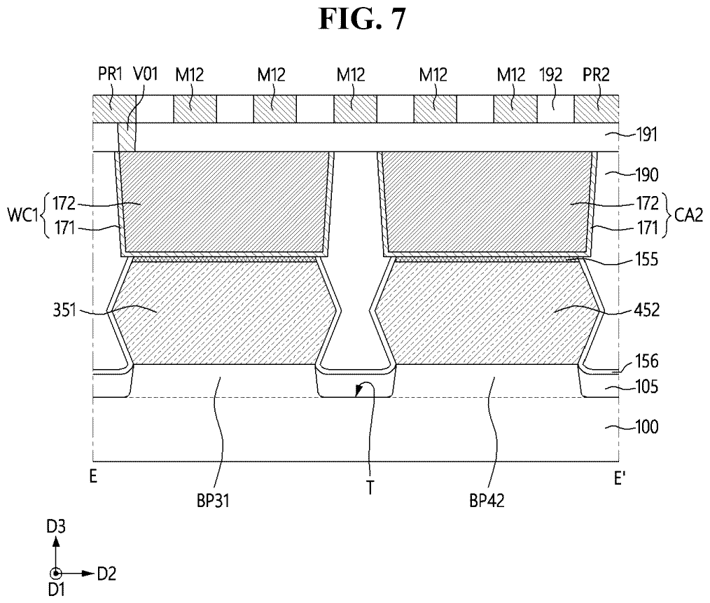

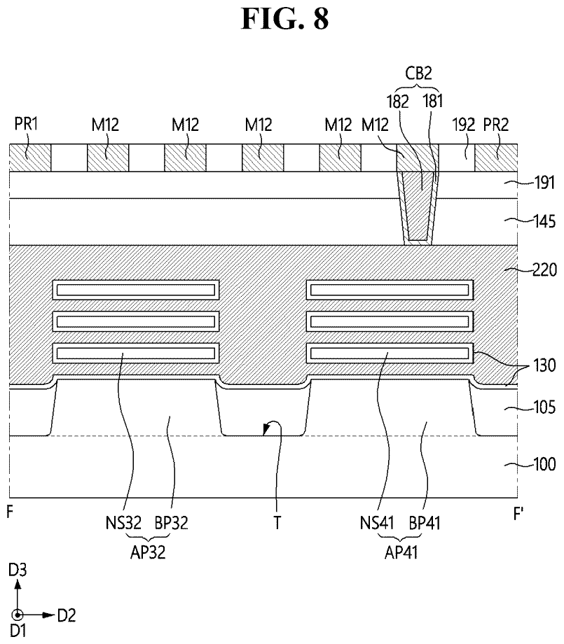

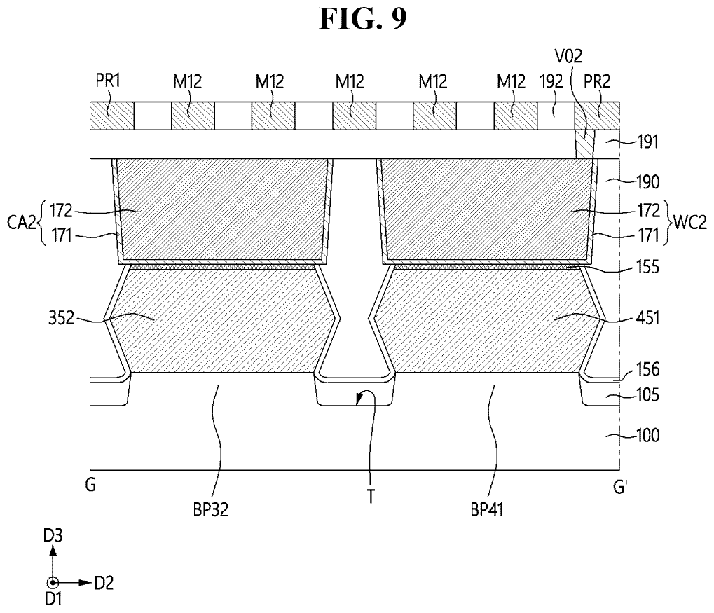

FIG. 2 is an enlarged view of area R of FIG. 1. FIG. 3 is a cross-sectional view taken along line A-A′ of FIG. 2. FIG. 4 is a cross-sectional view taken along line B-B′ of FIG. 2. FIG. 5 is a cross-sectional view taken along line C-C′ of FIG. 2. FIG. 6 is a cross-sectional view taken along line D-D′ of FIG. 2. FIG. 7 is a cross-sectional view taken along line E-E′ of FIG. 2. FIG. 8 is a cross-sectional view taken along line F-F′ of FIG. 2. FIG. 9 is a cross-sectional view taken along line G-G′ of FIG. 2.

Referring to FIGS. 1 through 7, the semiconductor device according to the embodiments includes a substrate 100, active patterns AP1 and AP2, dummy active patterns AP3 and AP4, a field insulating layer 105, gate structures GS, source/drain patterns 150, 250, 351, 352, 451 and 452, a source/drain etch stop layer 156, element isolation structures RC and FC, first through third interlayer insulating layers 190, 191 and 192, first power rails PR1, second power rails PR2, first wirings M11, second wirings M12, source/drain contacts CA1 and CA2, well contacts WC1 and WC2, and gate contacts CB1 and CB2.

The substrate 100 includes upper and lower surfaces that are opposite to each other in a third direction D3. The substrate 100 may be made of a semiconductor material or may include a semiconductor material. The substrate 100 may be a silicon substrate or a silicon-on-insulator (SOI) substrate. Alternatively, the substrate 100 may include, but is not limited to, silicon germanium, silicon germanium on insulator (SGOI), indium antimonide, lead telluride, indium arsenide, indium phosphide, gallium arsenide, or gallium antimonide.

Here, the first direction D1 and the second direction D2 may be directions parallel to the upper surface of the substrate 100. The first direction D1 and the second direction D2 may intersect each other. The third direction D3 may be a direction perpendicular to the upper surface of the substrate 100. The third direction D3 may intersect the first direction D1 and the second direction D2. A right side and a left side are defined based on the first direction D1, and an upper side and a lower side are defined based on the third direction D3.

The active patterns AP1 through AP4 are disposed on the substrate 100. For example, the active patterns AP1 through AP4 may be disposed on the upper surface of the substrate 100. Each of the active patterns AP1 through AP4 may extend in the first direction D1. The active patterns AP1 through AP4 may each be arranged in the second direction D2.

First active patterns AP1 and second active patterns AP2 are disposed in the standard cell area 12. Third active patterns AP3 and fourth active patterns AP4 are disposed in the ending cell area 14.

The first active patterns AP1 and the third active patterns AP3 may be spaced apart from each other in the first direction D1. The second active patterns AP2 and the fourth active patterns AP4 may be spaced apart from each other in the first direction D1. The first active patterns AP1 and the third active patterns AP3 may be adjacent to each first power rail PR1, and the second active patterns AP2 and the fourth active patterns AP4 may be adjacent to each second power rail PR2. The first and third active patterns AP1 and AP3 and the second and fourth active patterns AP2 and AP4 may be disposed between adjacent first and second power rails PR1 and PR2.

The first and third active patterns AP1 and AP3 are disposed in an area where transistors of the same conductivity type are formed. The second and fourth active patterns AP2 and AP4 are disposed in an area where transistors of the same conductivity type are formed.

For example, the first and third active patterns AP1 and AP3 may be disposed in an area where P-type transistors are formed. The second and fourth active patterns AP2 and AP4 may be disposed in an area where N-type transistors are formed.

Each of the third active patterns AP3 includes active pattern AP31 and active pattern AP32. Each of the fourth active patterns AP4 includes active pattern AP41 and active pattern AP42. The active patterns AP31, AP32, AP41, AP42 may also be referred to as “active sub-patterns AP31, AP32, AP41, AP42.”

Each of the active patterns AP1 through AP4 may be a multi-channel active pattern. For example, each of the first active patterns AP1 may include a first bottom pattern BP1 and a plurality of first sheet patterns NS1. Each of the second active patterns AP2 may include a second bottom pattern BP2 and a plurality of second sheet patterns NS2. The active pattern AP31 may include a bottom pattern BP31 and a plurality of sheet patterns NS31. The active pattern AP32 may include a bottom pattern BP32 and a plurality of sheet patterns NS32. The active pattern AP41 may include a bottom pattern BP41 and a plurality of sheet patterns NS41. In the semiconductor device according to the embodiments, the first active patterns AP1, the second active patterns AP2, the third active patterns AP3, and the fourth active patterns AP4 may each be an active pattern including nanosheets or nanowires.

The bottom patterns BP1, BP2, BP31, BP32, BP41 and BP42 may extend from the substrate 100. For example, the bottom patterns BP1, BP2, BP31, BP32, BP41 and BP42 may extend from the upper surface of the substrate 100. Each of the bottom patterns BP1, BP2, BP31, BP32, BP41 and BP42 may be a fin-shaped pattern.

The bottom patterns BP1, BP2, BP31, BP32, BP41 and BP42 may extend in the first direction D1. The first bottom pattern BP1 may be spaced apart from the bottom pattern BP31 and the bottom pattern BP32 in the first direction D1. The second bottom pattern BP2 may be spaced apart from the bottom pattern BP41 and the bottom pattern BP42 in the first direction D1. The first bottom pattern BP1 may be spaced apart from the second bottom pattern BP2 in the second direction D2. The bottom pattern BP31 and the bottom pattern BP32 may be spaced apart from the bottom pattern BP41 and the bottom pattern BP42 in the second direction D2.

The bottom patterns BP1, BP2, BP31, BP32, BP41 and BP42 may be separated by trenches T. For example, the upper surface of the substrate 100 may be bottom surfaces of the trenches T. Each of the bottom patterns BP1, BP2, BP31, BP32, BP41 and BP42 includes sidewalls extending in the first direction D1. The sidewalls of each of the bottom patterns BP1, BP2, BP31, BP32, BP41 and BP42 may be defined by the trenches T.

The bottom patterns BP1, BP2, BP31, BP32, BP41 and BP42 may be formed by partially etching the substrate 100 or may include an epitaxial layer grown from the substrate 100. The bottom patterns BP1, BP2, BP31, BP32, BP41 and BP42 may include silicon or germanium, which is an elemental semiconductor material. In addition, the bottom patterns BP1, BP2, BP31, BP32, BP41 and BP42 may include a compound semiconductor such as a group IV-IV compound semiconductor or a group III-V compound semiconductor.

The group IV-IV compound semiconductor may be, for example, a binary or ternary compound including two or more of carbon (C), silicon (Si), germanium (Ge) and tin (Sn) or may be a compound obtained by doping the binary or ternary compound with a group IV element.

The group III-V compound semiconductor may be, for example, a binary, ternary, or quaternary compound formed by bonding at least one of aluminum (Al), gallium (Ga) and indium (In), which are group III elements, with one of phosphorus (P), arsenic (As) and antimony (Sb), which are group V elements.

The first sheet patterns NS1 may be disposed on the first bottom pattern BP1. The first sheet patterns NS1 may be spaced apart from the first bottom pattern BP1 in the third direction D3. The second sheet patterns NS2 may be disposed on the second bottom pattern BP2. The second sheet patterns NS2 may be spaced apart from the second bottom pattern BP2 in the third direction D3. The sheet patterns NS31 may be disposed on the bottom pattern BP31. The sheet patterns NS31 may be spaced apart from the bottom pattern BP31 in the third direction D3. The sheet patterns NS32 may be disposed on the bottom pattern BP32. The sheet patterns NS32 may be spaced apart from the bottom pattern BP32 in the third direction D3. The sheet patterns NS41 may be disposed on the bottom pattern BP41. The sheet patterns NS41 may be spaced apart from the bottom pattern BP41 in the third direction D3. The sheet patterns NS42 may be disposed on the bottom pattern BP42. The sheet patterns NS42 may be spaced apart from the bottom pattern BP42 in the third direction D3.

Although each of the sheet patterns NS1, NS2, NS31, NS32, NS41 and NS42 are disposed in the third direction D3 in the drawings, this is merely an example used for ease of description, and the present disclosure is not limited to this example.

In the case of the first sheet patterns NS1, for example, a width of each of the first sheet patterns NS1 in the second direction D2 may increase or decrease proportionally to a width of the first bottom pattern BP1 in the second direction D2. Although the widths of the first sheet patterns NS1 on the first bottom pattern BP1 in the second direction D2 are the same in the drawings, the present disclosure is not limited thereto. The description of the first sheet patterns NS1 can also be applied to the second sheet patterns NS2, the sheet patterns NS31, the sheet patterns NS32, the sheet patterns NS41, and the sheet patterns NS42.

Each of the sheet patterns NS1, NS2, NS31, NS32, NS41 and NS42 may include one of an elemental semiconductor material, such as silicon or germanium, a group IV-IV compound semiconductor, and a group III-V compound semiconductor.

The field insulating layer 105 is disposed on the substrate 100. For example, the field insulating layer 105 may be disposed on the upper surface of the substrate 100. The field insulating layer 105 may fill/be in a space defined by at least a portion of each of the trenches T.

The field insulating layer 105 may be disposed on the substrate 100 between the bottom patterns BP1, BP2, BP31, BP32, BP41 and BP42. For example, the field insulating layer 105 may entirely cover or overlap the sidewalls of each of the bottom patterns BP1, BP2, BP31, BP32, BP41 and BP42. Unlike the drawings, and as another example, the field insulating layer 105 may partially cover or overlap the sidewalls of each of the bottom patterns BP1, BP2, BP31, BP32, BP41 and BP42. In this case, a portion of each of the bottom patterns BP1, BP2, BP31, BP32, BP41 and BP42 may extend above an upper surface of the field insulating layer 105 in the third direction D3.

The field insulating layer 105 does not cover nor overlaps an upper surface of each of the bottom patterns BP1, BP2, BP31, BP32, BP41 and BP42.

The field insulating layer 105 may include, for example, an oxide layer, a nitride layer, an oxynitride layer, or a combination thereof. Although the field insulating layer 105 is illustrated as a single layer, this is merely an example used for ease of description, and the present disclosure is not limited to this example.

The gate structures GS are disposed on the upper surface of the substrate 100. The gate structure GS may extend in the second direction D2. The gate structures GS may be spaced apart from each other in the first direction D1.

The gate structures GS may overlap the bottom patterns BP1, BP2, BP31, BP32, BP41 and BP42. The gate structures GS may overlap the sheet patterns NS1, NS2, NS31, NS32, NS41 and NS42.

Although the gate structures GS extend in the second direction D2 over different active patterns AP1 through AP4 in the drawings, the present disclosure is not limited thereto. For example, some of the gate structures GS may be separated into two parts by a gate isolation structure on the field insulating layer 105 and may be disposed on the first active patterns AP1 and the second active patterns AP2.

Each of the gate structures GS in the standard cell area 12 may include, for example, a first gate electrode 120, a gate insulating layer 130, gate spacers 140, and a gate capping pattern 145. Each of the gate structures GS in the ending cell area 14 may include, for example, a second gate electrode 220, a gate insulating layer 130, gate spacers 140, and a gate capping pattern 145. The first gate electrode 120 may be disposed in the standard cell area 12, and the second gate electrode 220 may be disposed in the ending cell area 14. The gate structures GS disposed in the ending cell area 14 are dummy gate structures, and the second gate electrodes 220 disposed in the ending cell area 14 are dummy gate electrodes.

Each of the gate structures GS may include a plurality of inner gate structures INT_GS formed between the sheet patterns NS1, NS2, NS31, NS32, NS41 or NS42 adjacent to each other in the third direction D3 and between the bottom pattern BP1, BP2, BP31, BP32, BP41 or BP42 and a sheet pattern NS1, NS2, NS31, NS32, NS41 or NS42.

In the case of a first active pattern AP1, for example, the inner gate structures INT_GS may be formed between the upper surface of the first bottom pattern BP1 and a lower surface of a first sheet pattern NS1 and between upper surfaces of first sheet patterns NS1 and lower surfaces of first sheet patterns NS1, which face each other in the third direction D3.

The number of inner gate structures INT_GS may be equal to the number of first sheet patterns NS1. The inner gate structures INT_GS contact the upper surface of the first bottom pattern BP1, the upper surfaces of the first sheet patterns NS1, and the lower surfaces of the first sheet patterns NS1.

Each of the inner gate structures INT_GS in the standard cell area 12 includes a first gate electrode 120 disposed between adjacent first sheet patterns NS1 or between the first bottom pattern BP1 and a first sheet pattern NS1 and a gate insulating layer 130.

In the case of the active pattern AP31, for example, each of the inner gate structures INT_GS in the ending cell area 14 includes a second gate electrode 220 disposed between adjacent sheet patterns NS31 or between the bottom pattern BP31 and a sheet pattern NS31 and a gate insulating layer 130.

The first gate electrode 120 may be disposed on the bottom patterns BP1 and BP2. The first gate electrode 120 may intersect the bottom patterns BP1 and BP2. The first gate electrode 120 may cover or overlap the sheet patterns NS1 and NS2. The second gate electrode 220 may be disposed on the bottom patterns BP31, BP32, BP41 and BP42. The second gate electrode 220 may intersect the bottom patterns BP31, BP32, BP41 and BP42. The second gate electrode 220 may cover or overlap the sheet patterns NS31, NS32, NS41 and NS42.

The gate electrodes 120 and 220 may include at least one of a metal, a metal alloy, a conductive metal nitride, a metal silicide, a doped semiconductor material, a conductive metal oxide, and a conductive metal oxynitride.

The gate insulating layer 130 may extend along the upper surface of the field insulating layer 105 and the upper surfaces of the bottom patterns BP1, BP2, BP31, BP32, BP41 and BP42. The gate insulating layer 130 may cover or overlap the sheet patterns NS1, NS2, NS31, NS32, NS41 and NS42. The gate insulating layer 130 may be disposed along the circumferences of the sheet patterns NS1, NS2, NS31, NS32, NS41 and NS42. The gate electrodes 120 and 220 are disposed on the gate insulating layer 130. The gate insulating layer 130 is disposed between the gate electrodes 120 and 220 and the sheet patterns NS1, NS2, NS31, NS32, NS41 and NS42.

The gate insulating layer 130 may include silicon oxide, silicon oxynitride, silicon nitride, or a high-k material having a higher dielectric constant than silicon oxide.

Although the gate insulating layer 130 is illustrated as a single layer, this is merely an example used for ease of description, and the present disclosure is not limited to this example. The gate insulating layer 130 may also include a plurality of layers. The gate insulating layer 130 may include an interfacial layer disposed between the active patterns AP1 through AP4 and the gate electrodes 120 and 220 and a high-k insulating layer. For example, the interfacial layer may not be formed along the profile of the upper surface of the field insulating layer 105.

The semiconductor device according to the embodiments may include a negative capacitance field effect transistor (FET) using a negative capacitor. For example, the gate insulating layer 130 may include a ferroelectric material layer having ferroelectric properties and a paraelectric material layer having paraelectric properties.

The ferroelectric material layer may have a negative capacitance, and the paraelectric material layer may have a positive capacitance. For example, when two or more capacitors are connected in series and the capacitance of each of the capacitors has a positive value, the total capacitance is reduced compared with the capacitance of each individual capacitor. On the other hand, when at least one of the capacitances of two or more capacitors connected in series has a negative value, the total capacitance may have a positive value and may be greater than an absolute value of each individual capacitance.

When the ferroelectric material layer having a negative capacitance and the paraelectric material layer having a positive capacitance are connected in series, the total capacitance value of the ferroelectric material layer and the paraelectric material layer connected in series may increase. As a result of the increased total capacitance value, a transistor including the ferroelectric material layer may have a sub-threshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. Here, for example, hafnium zirconium oxide may be a material obtained by doping hafnium oxide with zirconium (Zr). As another example, hafnium zirconium oxide may be a compound of hafnium (Hf), zirconium (Zr), and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material layer may vary according to the type of ferroelectric material that is included in the ferroelectric material layer.

When the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

When the dopant is aluminum (Al), the ferroelectric material layer may include 3 to 8 atomic % (at %) of aluminum. Here, the ratio of the dopant may be the ratio of aluminum to the sum of hafnium and aluminum.

When the dopant is silicon (Si), the ferroelectric material layer may include 2 to 10 at % of silicon. When the dopant is yttrium (Y), the ferroelectric material layer may include 2 to 10 at % of yttrium. When the dopant is gadolinium (Gd), the ferroelectric material layer may include 1 to 7 at % of gadolinium. When the dopant is zirconium (Zr), the ferroelectric material layer may include 50 to 80 at % of zirconium.

The paraelectric material layer may have paraelectric properties. The paraelectric material layer may include, for example, at least one of silicon oxide and a metal oxide having a high dielectric constant. The metal oxide included in the paraelectric material layer may include, but is not limited to, at least one of hafnium oxide, zirconium oxide, and aluminum oxide.

The ferroelectric material layer and the paraelectric material layer may include the same material. While the ferroelectric material layer has ferroelectric properties, the paraelectric material layer may not have ferroelectric properties. For example, when the ferroelectric material layer and the paraelectric material layer include hafnium oxide, the crystal structure of hafnium oxide included in the ferroelectric material layer is different from the crystal structure of hafnium oxide included in the paraelectric material layer.

The ferroelectric material layer may have a thickness having ferroelectric properties. The thickness of the ferroelectric material layer may be, but is not limited to, 0.5 to 10 nm. Each ferroelectric material may have a different critical thickness showing ferroelectric properties. Therefore, the thickness of the ferroelectric material layer may vary according to the ferroelectric material.

For example, the gate insulating layer 1330 may include one ferroelectric material layer. As another example, the gate insulating layer 130 may include a plurality of ferroelectric material layers spaced apart from each other. The gate insulating layer 130 may have a structure in which a plurality of ferroelectric material layers and a plurality of paraelectric material layers are alternately stacked.

The gate spacers 140 may be disposed on sidewalls of the gate electrodes 120 and 220. For example, the gate spacers 140 may be disposed on long sidewalls of each gate electrode. The gate spacers 140 may not be formed between the bottom patterns BP1, BP2, BP31, BP32, BP41 and BP42 and the sheet patterns NS1, NS2, NS31, NS32, NS41 and NS42 and between adjacent sheet patterns NS1, NS2, NS31, NS32, NS41 NS42 in the third direction D3.

The gate spacers 140 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiON), silicon oxycarbide (SiOC), and combinations thereof. Although each of the gate spacers 140 is illustrated as a single layer, this is merely an example used for ease of description, and the present disclosure is not limited to this example.

The gate capping pattern 145 may be disposed on the gate electrodes 120 and 220. An upper surface of the gate capping pattern 145 may be an upper surface of each of the gate structures GS. In one variation, the gate capping pattern 145 may be disposed between the gate spacers 140.

The gate capping pattern 145 may include, for example, at least one of silicon nitride (SiN), silicon oxynitride (SiON), silicon carbonitride (SiCN), silicon oxycarbonitride (SiOCN), and combinations thereof.

The source/drain patterns 150, 250, 351, 352, 451 and 452 may be disposed on the upper surface of the substrate 100. The source/drain patterns 150 and 250 may be disposed on side surfaces of the first gate electrodes 120. For example, the source/drain patterns 150 and 250 may contact the inner gate structures INT_GS in the standard cell area 12. The source/drain patterns 351, 352, 451 and 452 may be disposed on side surfaces of the second gate electrodes 220. For example, the source/drain patterns 351, 352, 451 and 452 may contact the inner gate structures INT_GS in the ending cell area 14.

First source/drain patterns 150 may be disposed on the first bottom pattern BP1. The first source/drain patterns 150 may contact each first active pattern AP1. The first source/drain patterns 150 may contact the first sheet patterns NS1. The first source/drain patterns 150 are connected to the first sheet patterns NS1 and the first bottom pattern BP1.

Second source/drain patterns 250 may be disposed on the second bottom pattern BP2. The second source/drain patterns 250 may contact each second active pattern AP2. The second source/drain patterns 250 may contact the second sheet patterns NS2. The second source/drain patterns 250 are connected to the second sheet patterns NS2 and the second bottom pattern BP2.

The source/drain patterns 351 may be disposed on the bottom pattern BP31. The source/drain patterns 351 may contact the active pattern AP31. The source/drain patterns 351 may contact the sheet patterns NS31. The source/drain patterns 351 are connected to the sheet patterns NS31 and the bottom pattern BP31. source/drain patterns 352 may be disposed on the bottom pattern BP32. The source/drain patterns 352 may contact the active pattern AP32. The source/drain patterns 352 may contact the sheet patterns NS32. The source/drain patterns 352 are connected to the sheet patterns NS32 and the bottom pattern BP32.

The source/drain patterns 451 may be disposed on the bottom pattern BP41. The source/drain patterns 451 may contact the active pattern AP41. The source/drain patterns 451 may contact the sheet patterns NS41. The source/drain patterns 451 are connected to the sheet patterns NS41 and the bottom pattern BP41. The source/drain patterns 452 may be disposed on the bottom pattern BP42. The source/drain patterns 452 may contact the active pattern AP42. The source/drain patterns 452 may contact the sheet patterns NS42. The source/drain patterns 452 are connected to the sheet patterns NS42 and the bottom pattern BP42.

Although not illustrated, and as another example, inner spacers may be further disposed between the inner gate structures INT_GS and the source/drain patterns 150, 250, 351, 352, 451 and 452. In this case, the source/drain patterns 150, 250, 351, 352, 451 and 452 do not contact the gate insulating layer 130 included in each of the inner gate structures INT_GS.

The source/drain patterns 150, 250, 351, 352, 451 and 452 may each be included in source/drain regions of a transistor that uses the sheet patterns NS1, NS2, NS31, NS32, NS41 or NS42 as a channel region.

Each of the source/drain patterns 150, 250, 351, 352, 451 and 452 may include an epitaxial pattern. Each of the source/drain patterns 150, 250, 351, 352, 451 and 452 may include a semiconductor material.

The first source/drain patterns 150, the source/drain patterns 351, and the source/drain patterns 352 may include a p-type dopant. The p-type dopant may include, but is not limited to, at least one of boron (B) and gallium (Ga). The second source/drain patterns 250, the source/drain patterns 451, and the source/drain patterns 452 may include an n-type dopant. The n-type dopant may include, but is not limited to, at least one of phosphorus (P), arsenic (As), antimony (Sb), and bismuth (Bi).

The source/drain etch stop layer 156 may extend along outer walls of the gate spacers 140 and sidewalls of the source/drain patterns 150, 250, 351, 352, 451 and 452. The source/drain etch stop layer 156 may extend along the upper surface of the field insulating layer 105.

The source/drain etch stop layer 156 may not extend along sidewalls of the gate capping pattern 145. In one variation, the source/drain etch stop layer 156 may also extend along the sidewalls of the gate capping pattern 145.

The source/drain etch stop layer 156 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

The element isolation structures RC and FC are disposed on the substrate 100. The element isolation structures RC and FC may be disposed on the upper surface of the substrate 100. The element isolation structures RC and FC may extend in the second direction D2. The element isolation structures RC and FC may separate adjacent cells.

First element isolation structures RC may overlap the gate electrodes 120 and 220. The first element isolation structures RC may be disposed between the source/drain patterns 150, 250, 351, 352, 451 and 452 that are adjacent to each other in the first direction D1. A second element isolation structure FC may overlap a pair of gate electrodes 120 and 220 that are adjacent to each other in the second direction D2. A width of the second element isolation structure FC in the first direction D1 may be greater than a width of each of the first element isolation structures RC in the first direction D1.

The element isolation structures RC and FC may be disposed between the first active patterns AP1 and the third active patterns AP3. The element isolation structures RC and FC may be disposed between the second active patterns AP2 and the fourth active patterns AP4. The element isolation structures RC and FC may be disposed between the active patterns AP1, AP2, AP3 or AP4 that are adjacent to each other in the first direction D1. For example, the first element isolation structures RC may be disposed between the first active patterns AP1 that are adjacent to each other in the first direction D1.

The element isolation structures RC and FC may separate the first bottom patterns BP1 and the third bottom patterns BP3. The element isolation structures RC and FC may separate the second bottom patterns BP2 and the fourth bottom patterns BP4. The element isolation structures RC and FC may be disposed between the bottom patterns BP1, BP2, BP31, BP32, BP41 or BP42 that are adjacent to each other in the first direction D1. For example, the first element isolation structures RC may be disposed between the first bottom patterns BP1 that are adjacent to each other in the first direction D1.

Upper surfaces of the element isolation structures RC and FC may be at the same height as the upper surface of the gate capping pattern 145 from the upper surface of the substrate 100 (i.e., the upper surfaces of the element isolation structures RC and FC extend from the upper surface of the substrate 100 by a same distance). In one variation, the upper surfaces of the element isolation structures RC and FC may also be at a higher height than the upper surface of the gate capping pattern 145 from the upper surface of the substrate 100 (i.e., the upper surfaces of the element isolation structures RC and FC extend from the upper surface of the substrate 100 by a greater distance than a distance in which the upper surface of the gate capping pattern 145 extends from the upper surface of the substrate 100).

The element isolation structures RC and FC may include an insulating material. Although each of the element isolation structures RC and FC is illustrated as a single layer, the present disclosure is not limited thereto.

For example, an insulating residual pattern may be disposed between the element isolation structures RC and FC and the source/drain patterns 150, 250, 350 and 450. The insulating residual pattern may include the same material as the gate insulating layer 130.

A first interlayer insulating layer 190 is disposed on the upper surface of the substrate 100. The first interlayer insulating layer 190 may be disposed on the source/drain patterns 150, 250, 351, 352, 451 and 452. The first interlayer insulating layer 190 may be disposed on the element isolation structures RC and FC. The first interlayer insulating layer 190 may not cover nor overlap the upper surface of the gate capping pattern 145. A second interlayer insulating layer 191 is disposed on the first interlayer insulating layer 190. The second interlayer insulating layer 191 may not cover nor overlap upper surfaces of gate contacts CB1 and CB2. A third interlayer insulating layer 192 is disposed on the second interlayer insulating layer 191.

Each of the first through third interlayer insulating layers 190 through 192 may include, for example, at least one of silicon oxide, silicon nitride, silicon oxynitride, and a low-k material.

The first power rails PR1, the second power rails PR2, the first wirings M11, and the second wirings M12 may be disposed in the third interlayer insulating layer 192. Each of the first power rails PR1, the second power rails PR2, the first wirings M11, and the second wirings M12 may extend in the first direction D1. The first power rails PR1, the second power rails PR2, the first wirings M11, and the second wirings M12 are disposed at the same metal level.

The first power rails PR1 and the second power rails PR2 may be alternately disposed along the second direction D2. The first power rails PR1 may provide a first voltage, and the second power rails PR2 may provide a second voltage different from the first voltage VDD. For example, the first voltage may be a positive (+) voltage, and the second voltage may be a ground (GND) voltage or a negative (−) voltage.

The first wirings M11 are disposed in the standard cell area 12, and the second wirings M12 are disposed in the ending cell area 14. The first wirings M11 do not extend to the ending cell area 14. The first wirings M11 and the second wirings M12 are separated from each other.

The first wirings M11 and the second wirings M12 are disposed at the same height from the upper surface of the substrate 100. The first wirings M11 and the second wirings M12 may be, for example, signal lines that transmit signals. The first wirings M11 and the second wirings M12 may be arranged along the second direction D2 between the first and second power rails PR1 and PR2.

The source/drain contacts CA1 and CA2 and the well contacts WC1 and WC2 are disposed on the upper surface of the substrate 100. First source/drain contacts CA1 are disposed in the standard cell area 12. Second source/drain contacts CA2 are disposed in the ending cell area 14. The well contacts WC1 and WC2 may be disposed in the ending cell area 14.

The first source/drain contacts CA1 may be disposed on the first and second source/drain patterns 150 and 250. The first source/drain contacts CA1 may be electrically connected to the first and second source/drain patterns 150 and 250, respectively.

The second source/drain contacts CA2 may be disposed on the source/drain patterns 352 and the source/drain patterns 452. The second source/drain contacts CA2 may be electrically connected to the source/drain patterns 352 and the source/drain patterns 452, respectively.

First well contacts WC1 may be disposed on the source/drain patterns 351. The first well contacts WC1 may be electrically connected to the source/drain patterns 351. The first well contacts WC1 may be connected to each first power rail PR1 through first vias V01. The source/drain patterns 351 may receive the first voltage through the first well contacts WC1 and the first vias V01.

Second well contacts WC2 may be disposed on the source/drain patterns 451. The second well contacts WC2 may be electrically connected to the source/drain patterns 451. The second well contacts WC2 may be connected to each second power rail PR2 through second vias V02. The source/drain patterns 451 may receive the second voltage through the second well contacts WC2 and the second vias V02.

Each of the source/drain contacts CA1 and CA2 and the well contacts WC1 and WC2 may include a first barrier layer 171 and a first filling layer 172.

A contact silicide layer 155 may be disposed between the first source/drain contacts CA1 and the first source/drain patterns 150, between the first source/drain contacts CA1 and the second source/drain patterns 250, between the second source/drain contacts CA2 and the source/drain patterns 352, between the second source/drain contacts CA2 and the source/drain patterns 452, between the first well contacts WC1 and the source/drain patterns 351, and between the second well contacts WC2 and the source/drain patterns 451.

First gate contacts CB1 are disposed in the standard cell area 12, and second gate contacts CB2 are disposed in the ending cell area 14.

The first gate contacts CB1 are disposed on the first gate electrodes 120. Each of the first gate contacts CB1 may extend into the gate capping pattern 145. The first gate contacts CB1 are connected to the first gate electrodes 120. The first gate contacts CB1 may be connected to the first wirings M11. The first gate contacts CB1 may contact the first wirings M11 and the first gate electrodes 120.

The second gate contacts CB2 are disposed on the second gate electrodes 220. Each of the second gate contacts CB2 may extend into the gate capping pattern 145. The second gate contacts CB2 are connected to the second gate electrodes 220. The second gate contacts CB2 may be connected to the second wirings M12. The second gate contacts CB2 may contact the second wirings M12 and the second gate electrodes 220. The second gate contacts CB2 are dummy gate contacts. The second gate contacts CB2 are not electrically connected to the first gate contacts CB1. Signals provided to the first gate electrodes 120 are not provided to the second gate electrodes 220. For example, the first wirings M11 connected to the first gate contacts CB1 may be separated from the second wirings M12 connected to the second gate contacts CB2. The first wirings M11 connected to the standard cell area 12 may not be connected to the second wirings M12 connected to the ending cell area 14.

The second gate contacts CB2 may be disposed on the active pattern AP31 on which the first well contacts WC1 are disposed and the active pattern AP41 on which the second well contacts WC2 are disposed. The second gate contacts CB2 may be disposed between the active pattern AP31 and a second wiring M12 and between the active pattern AP41 and a second wiring M12.

A plurality of second wirings M12 are disposed between the first and second power rails PR1 and PR2 that are adjacent to each other. The second wirings M12 are arranged in the second direction D2. The second gate contacts CB2 are disposed on the second wirings M12 adjacent to each first power rail PR1. The second gate contacts CB2 are disposed on the second wirings M12 adjacent to each second power rail PR2. The second gate contacts CB2 are disposed on the second wirings M12 closest to each first power rail PR1 and the second wirings M12 closest to each second power rail PR2. That is, the second gate contacts CB2 are not disposed on the second wirings M12 not closest to each first power rail PR1 and the second wirings M12 not closest to each second power rail PR2. Since widths of the first and second power rails PR1 and PR2 are greater than widths of the first and second wirings M11 and M12 in the second direction D2, when the second gate contacts CB2 are formed on the second wirings M12 adjacent to each first power rail PR1 or each second power rail PR2, the process margin of the second gate contacts CB2 may be increased or improved.

For example, one second gate electrode 220 may be disposed between the second gate contacts CB2 adjacent to each other in the first direction D1. That is, the second gate contacts CB2 may be disposed on two second gate electrodes 220 excluding a second gate electrode 220 disposed in the middle among the three second gate electrodes 220 sequentially arranged along the first direction D1. A distance S between the second gate contacts CB2 that are adjacent to each other in the first direction D1 may be, for example, 72 to 198 nm.

The second gate contacts CB2 have the same size as the first gate contacts CB1. A depth of each second gate contact CB2 in the third direction D3 is the same as a depth of each first gate contacts CB1 in the third direction D3. A length of each second gate contact CB2 in the first direction D1 is the same as a length of each first gate contact CB1 in the first direction D1. A length of each second gate contact CB2 in the second direction D2 is the same as a length of each first gate contact CB1 in the second direction D2. The second gate contacts CB2 may be formed through the same process as the first gate contacts CB1.

Each of the gate contacts CB1 and CB2 may include a second barrier layer 181 and a second filling layer 182.

Each of the first barrier layer 171 and the second barrier layer 181 may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a 2D material. Each of the first filling layer 172 and the second filling layer 182 may include, for example, at least one of aluminum (Al), tungsten (W), cobalt (Co), ruthenium (Ru), copper (Cu), silver (Ag), gold (Au), manganese (Mn), and molybdenum (Mo).

The semiconductor device according to the embodiments of the present disclosure includes the second gate contacts CB2 in the ending cell area 14. Accordingly, a difference between the density of the second gate contacts CB2 in the ending cell area 14 and the density of the first gate contacts CB1 in the standard cell area 12 may be reduced. This may improve or enhance a planarization effect during a chemical mechanical planarization (CMP) process (for example, during a CMP process of the first wirings M11 and the second wirings M12).

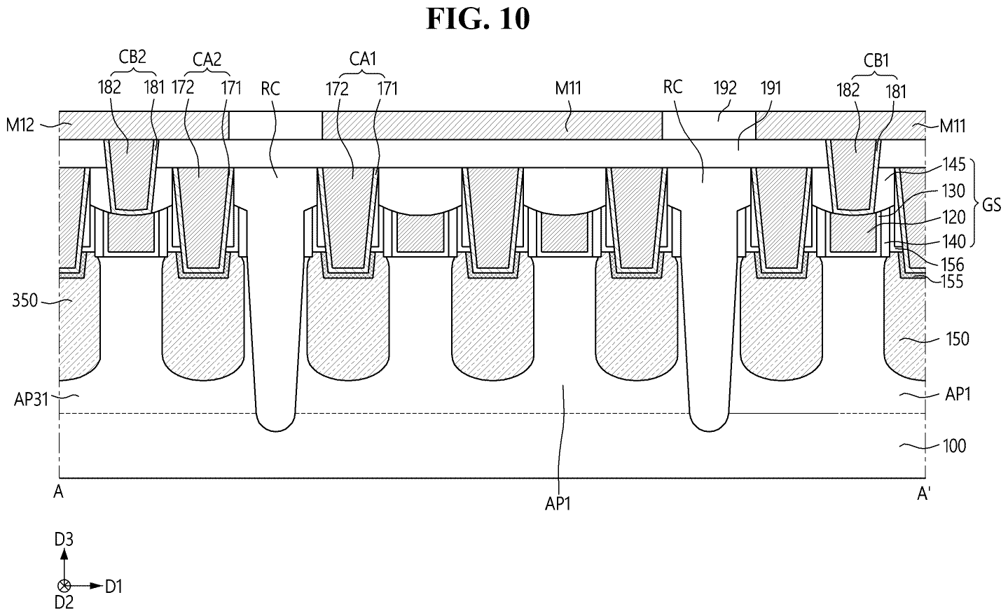

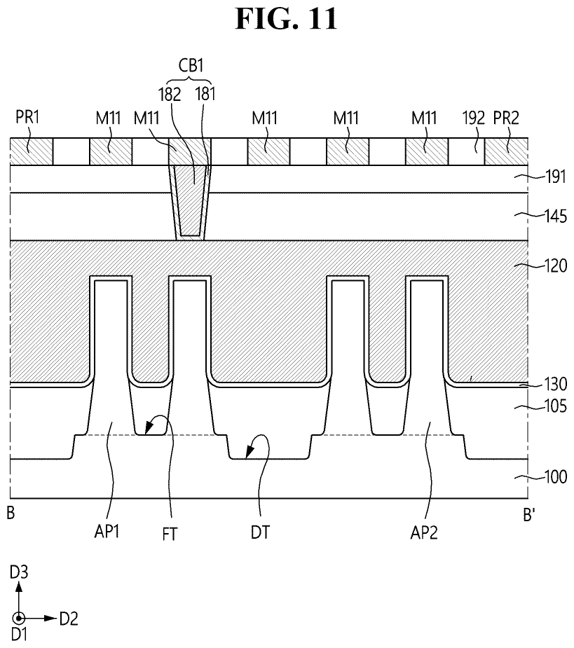

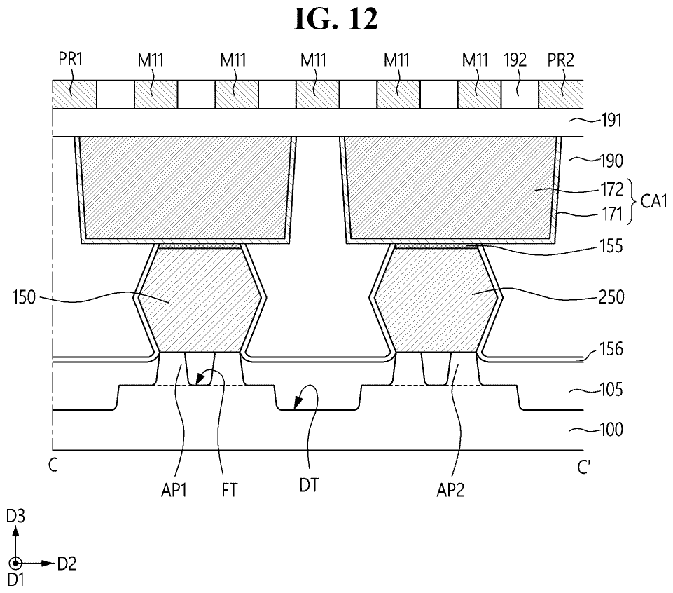

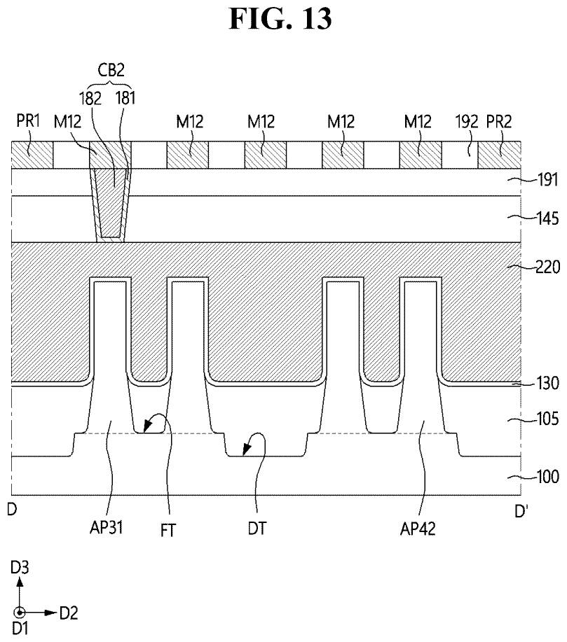

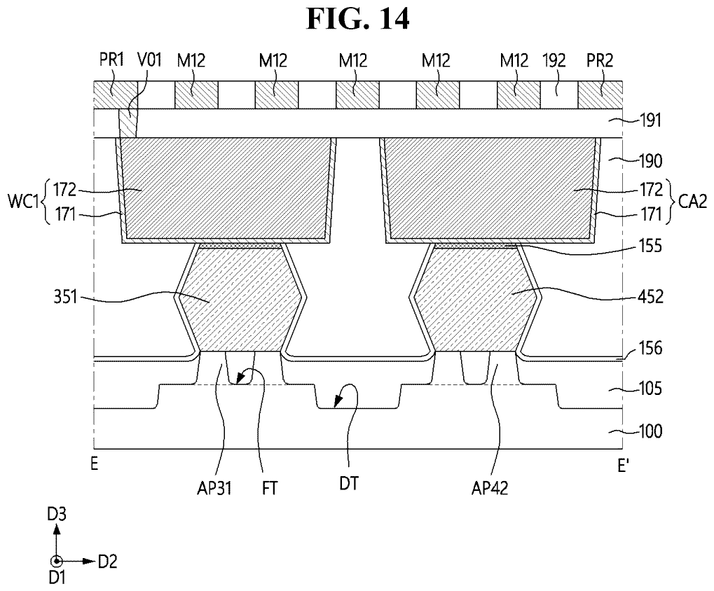

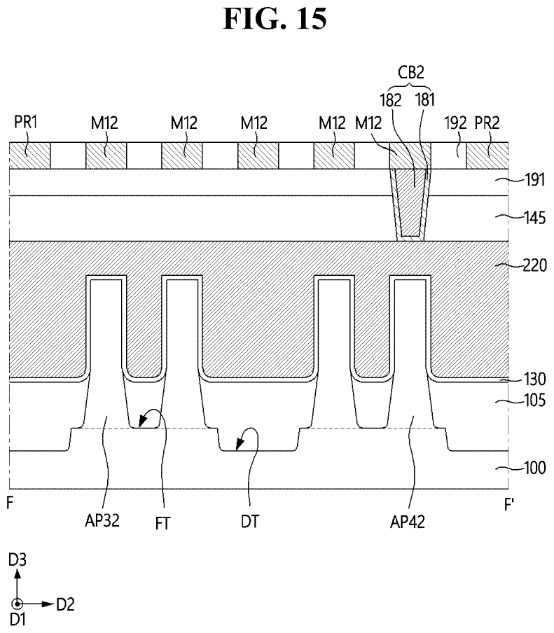

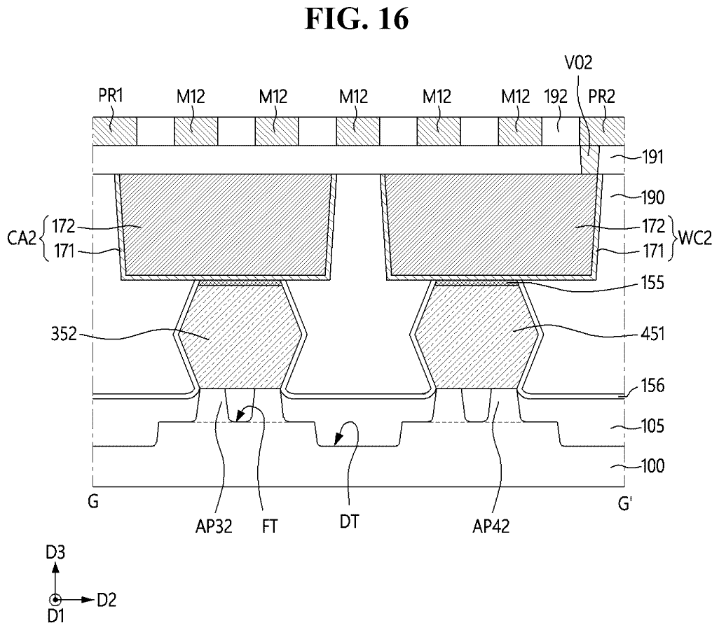

FIGS. 10 through 16 are cross-sectional views of a semiconductor device according to embodiments. For reference, FIG. 10 is a cross-sectional view taken along line A-A′ of FIG. 2. FIG. 11 is a cross-sectional view taken along line B-B′ of FIG. 2. FIG. 12 is a cross-sectional view taken along line C-C′ of FIG. 2. FIG. 13 is a cross-sectional view taken along line D-D′ of FIG. 2. FIG. 14 is a cross-sectional view taken along line E-E′ of FIG. 2. FIG. 15 is a cross-sectional view taken along line F-F′ of FIG. 2. FIG. 16 is a cross-sectional view taken along line G-G′ of FIG. 2. For ease of description, the following description will focus on differences from the semiconductor device described above with reference to FIGS. 1 through 9.

Referring to FIGS. 10 through 16, in the semiconductor device according to the embodiments, each of active patterns AP1 through AP4 does not include sheet patterns.

The active patterns AP1 through AP4 may be fin-shaped patterns extending above an upper surface of a field insulating layer 105. The field insulating layer 105 may partially cover or overlap sidewalls of the active patterns AP1 through AP4.

First through fourth active patterns AP1 through AP4 extending above the upper surface of the field insulating layer 105 may be used as channel regions of transistors.

In the semiconductor device illustrated in FIGS. 10 through 16, the gate structure GS does not include inner gate structures INT_GS.

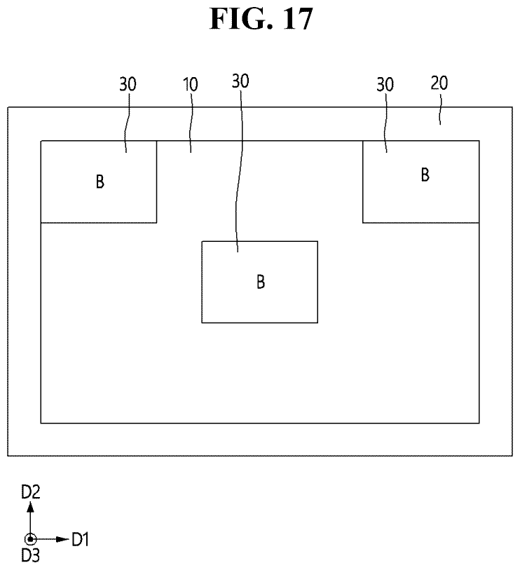

Referring to FIG. 17, a semiconductor device according to embodiments includes a cell area 10, an input/output area 20, and block areas 30.

The cell area 10 includes the standard cell area 12 and the ending cell area 14 described with reference to FIGS. 1 through 16.

Input/output pads and an input/output buffer or driver for exchanging data or signals with the outside of the chip may be formed in the input/output area 20.

A memory, an analog circuit block, a static random access memory (SRAM), a CPU, or the like may be formed in each of the block areas 30. The analog circuit block may be, for example, a phase locked loop (PLL).

The cell area 10, the input/output area 20, and the block areas 30 may be spaced apart from each other. For example, dummy patterns may be disposed in a field area between the cell area 10 and the input/output area 20 or between the cell area 10 and the block areas 30. The semiconductor device according to the embodiments includes second gate contacts CB2 in the ending cell area 14. Accordingly, a difference between the density of gate contacts in the standard cell area 12, the density of gate contacts in the ending cell area 14, and the density of gate contacts in the field area may be reduced, thereby improving or enhancing a planarization effect during a CMP process.

While the present disclosure has been particularly illustrated and described with reference to exemplary embodiments thereof, it will be understood by those of ordinary skill in the art that various changes in form and detail may be made therein without departing from the spirit and scope of the present disclosure as defined by the following claims. The exemplary embodiments should be considered in a descriptive sense only and not for purposes of limitation.

What is claimed is:

1. A semiconductor device comprising:
a substrate comprising a standard cell area and an ending cell area that at least partially surrounds the standard cell area;
a first active pattern in the standard cell area;
a first wiring that extends in a first direction and is on the first active pattern;
a first gate electrode that extends in a second direction and is on the first active pattern;
a first gate contact;
a second active pattern in the ending cell area;
a second wiring that extends in the first direction and is on the second active pattern;
a second gate electrode that extends in the second direction and is on the second active pattern; and
a second gate contact.

2. The semiconductor device of claim 1, wherein the first gate contact is electrically connected to the first gate electrode and the first wiring, and wherein the second gate contact is electrically connected to the second gate electrode and the second wiring.

3. The semiconductor device of claim 1, wherein the first gate contact and the second gate contact have a same length in at least one of the first direction and the second direction.

4. The semiconductor device of claim 1, further comprising:
a first power rail that extends in the first direction;
a second power rail that extends in the first direction and is spaced apart from the first power rail in the second direction, and
a plurality of the second wirings,
wherein the plurality of the second wirings are between the first power rail and the second power rail in the second direction,
wherein the second gate contact is on a given second wiring from among the plurality of the second wirings, and
wherein the given second wiring is adjacent to the first power rail or the second power rail.

5. The semiconductor device of claim 1, further comprising:
a first power rail that extends in the first direction; and
a second power rail that extends in the first direction and is spaced apart from the first power rail in the second direction,
wherein the second active pattern comprises a third active sub-pattern that is electrically connected to the first power rail and a fourth active sub-pattern that is electrically connected to the second power rail.

6. The semiconductor device of claim 1, wherein the first wiring and the second wiring are not electrically connected.

7. The semiconductor device of claim 1, wherein:
the first active pattern comprises a first fin-shaped pattern that extends in the first direction and extends from the substrate,
the second active pattern comprises a second fin-shaped pattern that extends in the first direction and extends from the substrate,
the first gate electrode overlaps the first fin-shaped pattern, and
the second gate electrode overlaps the second fin-shaped pattern.

8. The semiconductor device of claim 1, wherein:
the first active pattern comprises a first fin-shaped pattern that extends in the first direction and extends from the substrate,
the first active pattern comprises a first sheet pattern that is spaced apart from the first fin-shaped pattern,
the second active pattern comprises a second fin-shaped pattern that extends in the first direction and extends from the substrate,
the second active pattern comprises a second sheet pattern that is spaced apart from the second fin-shaped pattern,
the first gate electrode overlaps the first sheet pattern, and
the second gate electrode overlaps the second sheet pattern.

9. A semiconductor device comprising:
a substrate comprising a standard cell area and an ending cell area that at least partially surrounds the standard cell area;
an active pattern in the ending cell area;
a power rail that extends in a first direction and is on the active pattern;
a wiring that extends in the first direction and is on the active pattern;
one or more gate electrodes that extend in a second direction and are on the active pattern;
a gate contact between the gate electrode and the wiring;
a source/drain pattern on the active pattern and on one side of the gate electrode; and
a well contact between the source/drain pattern and the power rail.

10. The semiconductor device of claim 9, wherein the wiring is adjacent to the power rail.

11. The semiconductor device of claim 9, wherein:
the one or more gate electrodes comprise a first gate electrode, a second gate electrode, and a third gate electrode that are spaced apart in the first direction, and
the gate contact is on the first gate electrode and the third gate electrode and is not on the second gate electrode.

12. The semiconductor device of claim 9, wherein the wiring does not extend into the standard cell area.

13. The semiconductor device of claim 9, wherein the power rail and the wiring extend by a same distance from the substrate.

14. A semiconductor device comprising:
a substrate;
a first active pattern on the substrate;
a second active pattern on the substrate;
a first gate electrode that is on the first active pattern and extends in a second direction;
a second gate electrode that is on the second active pattern and extends in the second direction;
a first wiring that extends in a first direction and is on the first active pattern;
a second wiring that extends in the first direction and is on the second active pattern;
a power rail that extends in the first direction and is on the substrate;
a first gate contact between the first gate electrode and the first wiring; and
a second gate contact between the second gate electrode and the second wiring,
wherein the second active pattern is electrically connected to the power rail, and
wherein the first wiring and the second wiring are not electrically connected to each other.

15. The semiconductor device of claim 14, wherein the second wiring is adjacent to the power rail.

16. The semiconductor device of claim 14, wherein:
the first active pattern comprises a first fin-shaped pattern and a first sheet pattern that is on and spaced apart from the first fin-shaped pattern, and
the second active pattern comprises a second fin-shaped pattern and a second sheet pattern that is on and spaced apart from the second fin-shaped pattern.

17. The semiconductor device of claim 14, wherein the first gate contact and the second gate contact have a same length in at least one of the first direction and the second direction.

18. The semiconductor device of claim 14, wherein the first gate contact and the second gate contact have a same length in a direction that is perpendicular to an upper surface of the substrate.

19. The semiconductor device of claim 14, wherein the second active pattern is adjacent to the first active pattern in the first direction or the second direction.

20. The semiconductor device of claim 14, further comprising:
a source/drain pattern that is on the second active pattern and on one side of the second gate electrode; and
a well contact between the source/drain pattern and the power rail.
